(19) United States
(12) Patent Application Publication
(10) Pub. No.: US 2025/0293139 A1
(43) Pub. Date: Sep. 18, 2025

(54) SEMICONDUCTOR PACKAGE

(71) Applicant: Samsung Electronics Co., Ltd., Suwon-si (KR)

(72) Inventors: Junhyun AN, Suwon-si (KR); Unbyoung KANG, Suwon-si (KR); Seokbong PARK, Suwon-si (KR); Hyojin YUN, Suwon-si (KR); Seunghun CHAE, Suwon-si (KR)

(73) Assignee: Samsung Electronics Co., Ltd., Suwon-si (KR)

(21) Appl. No.: 18/799,692

(22) Filed: Aug. 9, 2024

(30) Foreign Application Priority Data
Mar. 18, 2024 (KR) 10-2024-0037174

(51) Int. Cl. H01L 23/498; H01L 21/56; H01L 23/00; H01L 23/29; H01L 23/31; H01L 25/065

(52) U.S. Cl. CPC H01L 23/49838; H01L 23/29; H01L 23/3128; H01L 23/3135; H01L 23/49833; H01L 23/49866; H01L 21/56; H01L 24/13; H01L 24/16; H01L 24/48; H01L 25/0657; H01L 2224/13147; H01L 2224/13611; H01L 2224/16225; H01L 2224/48147; H01L 2224/48227; H01L 2225/06506; H01L 2225/0651; H01L 2225/06562; H01L 2924/1815

(57) ABSTRACT

A semiconductor package includes a lower redistribution structure including first pads and second pads, a plurality of posts on the first pads, a semiconductor chip on the second pads, a mold layer covering at least a portion of each post of the plurality of posts and the semiconductor chip, first side barrier layers between the mold layer and respective side surfaces of the first pads and between the mold layer and respective side surfaces of the plurality of posts, second side barrier layers between the mold layer and respective side surfaces of the second pads, an upper redistribution structure on the mold layer and including an upper redistribution layer electrically connected to the plurality of posts, and external connection bumps below the lower redistribution structure.

### CROSS-REFERENCE TO RELATED APPLICATION(S)

This application claims the benefit under 35 USC 119 (a) of Korean Patent Application No. 10-2024-0037174 filed on Mar. 18, 2024 in the Korean Intellectual Property Office, the entire disclosure of which is incorporated herein by reference for all purposes.

### BACKGROUND

The present inventive concepts relate to semiconductor packages.

As electronic devices become lighter and are implemented with higher performance, there is a demand for the development of miniaturized and high-performance semiconductor packages in the semiconductor package field. Accordingly, development of a Package on Package (PoP) structure in which a plurality of packages are stacked is undertaken.

### SUMMARY

Some example embodiments of the inventive concepts provide a semiconductor package having improved reliability and yield.

According to some example embodiments, a semiconductor package may include a lower redistribution structure. The lower redistribution structure may include a lower redistribution layer and first pads and second pads electrically connected to the lower redistribution layer. The semiconductor package may include a plurality of posts on the first pads of the lower redistribution structure; a semiconductor chip on the second pads of the lower redistribution structure and including connection pads electrically connected to the second pads; a mold layer covering at least a portion of each post of the plurality of respective posts and the semiconductor chip; first side barrier layers between the mold layer and respective side surfaces of the first pads and between the mold layer and respective side surfaces of the plurality of posts; second side barrier layers between the mold layer and respective side surfaces of the second pads; an upper redistribution structure on the mold layer and including an upper redistribution layer electrically connected to the plurality of posts; and external connection bumps below the lower redistribution structure and electrically connected to the lower redistribution layer.

According to some example embodiments, a semiconductor package may include a lower redistribution structure. The lower redistribution structure may include a lower redistribution layer and first pads and second pads electrically connected to the lower redistribution layer. The semiconductor package may include a plurality of posts on the first pads of the lower redistribution structure; a semiconductor chip on the second pads of the lower redistribution structure; a mold layer covering at least a portion of each post of the plurality of posts and the semiconductor chip; side barrier layers between the mold layer and respective side surfaces of the first pads and between the mold layer and respective side surfaces of the plurality of posts; an upper redistribution structure on the mold layer and including an upper redistribution layer electrically connected to the plurality of posts; and external connection bumps below the lower redistribution structure and electrically connected to the lower redistribution layer. The side barrier layers and the plurality of posts may include different metals.

According to some example embodiments, a semiconductor package may include a lower redistribution structure. The lower redistribution structure may include a lower redistribution layer and first pads and second pads electrically connected to the lower redistribution layer. The semiconductor package may include a plurality of posts on the first pads of the lower redistribution structure; a semiconductor chip on the second pads of the lower redistribution structure; a mold layer covering at least a portion of each of the plurality of posts and the semiconductor chip; side barrier layers between the mold layer and respective first pads of the first pads and between the mold layer and respective posts of the plurality of posts; and an upper redistribution structure on the mold layer. The upper redistribution structure may include an upper redistribution layer and an upper redistribution via electrically connecting the upper redistribution layer and the plurality of posts. Each post of the plurality of posts may have a side surface in contact with the side barrier layers, a lower surface exposed from the side barrier layers and in contact with the first pads, and an upper surface exposed from the side barrier layers and in contact with the upper redistribution via.

### BRIEF DESCRIPTION OF THE DRAWINGS

The above and other aspects, features, and advantages of the present inventive concepts will be more clearly understood from the following detailed description, taken in conjunction with the accompanying drawings, in which:

FIG. 1A is a cross-sectional view of a semiconductor package according to some example embodiments, and FIG. 1B is a plan view taken along line I-I′ of FIG. 1A according to some example embodiments;

FIG. 2A is a partially enlarged view of area ‘A’ of FIG. 1A according to some example embodiments, FIG. 2B is a plan view taken along line II-II′ of FIG. 2A according to some example embodiments, and FIG. 2C is a partially enlarged view of area ‘B’ of FIG. 1A according to some example embodiments;

FIG. 3 is a partially enlarged view of area ‘A’ of FIG. 1A illustrating a semiconductor package of an illustrative modified example according to some example embodiments;

FIG. 4 is a partially enlarged view of area ‘A’ of FIG. 1A illustrating a semiconductor package of an illustrative modification according to some example embodiments;

FIG. 5 is a partially enlarged view of area ‘A’ of FIG. 1A illustrating a semiconductor package of an illustrative modification according to some example embodiments;

FIG. 6 is a partially enlarged view of area ‘B’ of FIG. 1A illustrating a semiconductor package of an illustrative modification according to some example embodiments;

FIG. 7 is a cross-sectional view of a semiconductor package according to some example embodiments;

FIG. 8 is a cross-sectional view of a semiconductor package according to some example embodiments; and

FIGS. 9A, 9B, 9C, 9D, 9E, and 9F are diagrams illustrating a process of manufacturing a semiconductor package according to some example embodiments.

### DETAILED DESCRIPTION

Hereinafter, with reference to the accompanying drawings, some example embodiments of the present inventive concepts will be described as follows. Unless otherwise specified, in this specification, terms such as ‘upper,’ ‘upper surface,’ ‘lower,’ ‘lower surface,’ ‘side’ and the like are based on the drawings, and actually, may vary depending on the direction in which the components are disposed. In the drawings, the same elements are denoted by the same reference numerals, and a repeated description thereof will be omitted.

Additionally, ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. Additionally, terms referenced by a specific ordinal number (for example, “first” in a particular claim) may be described elsewhere with a different ordinal number (for example, “second” in the specification or another claim).

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below or horizontally adjacent to the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these numerical values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

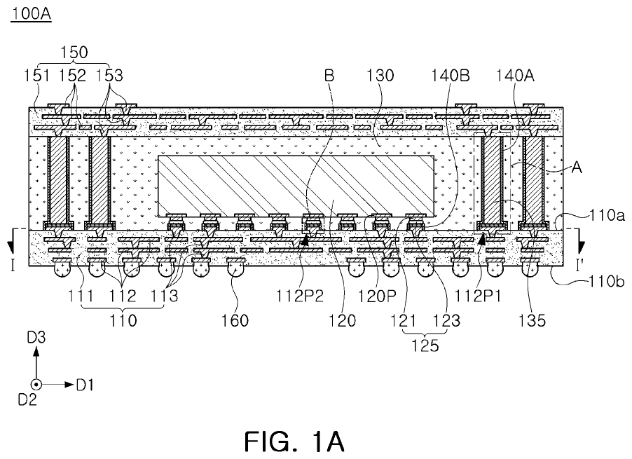

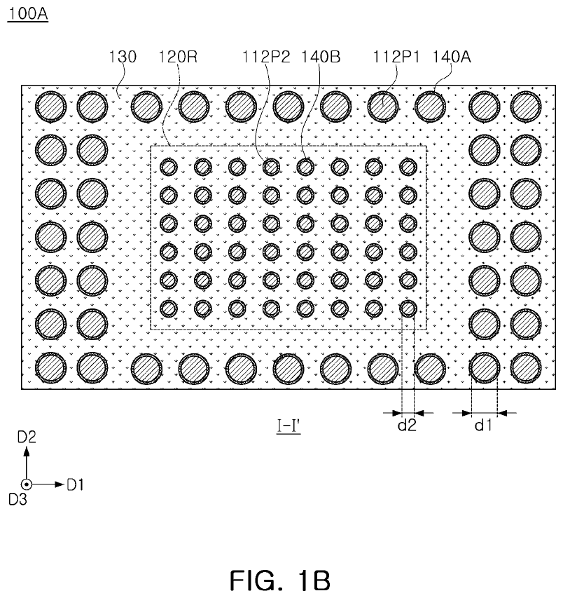

FIG. 1A is a cross-sectional view of a semiconductor package 100A according to some example embodiments, while FIG. 1B is a plan view taken along line I-I′ of FIG. 1A according to some example embodiments.

Referring to FIGS. 1A and 1B, a semiconductor package 100A according to some example embodiments may include a lower redistribution structure 110, a semiconductor chip (or ‘chip structure’) 120, a mold layer 130, a plurality of posts 135, side barrier layers 140A (or ‘first side barrier layers’), and an upper redistribution structure 150. In some example embodiments, the semiconductor package 100A may further include external connection bumps 160.

The lower redistribution structure 110 is a support substrate on which the chip structure 120 is mounted, and may include a lower insulating layer 111, lower redistribution layers 112, and lower redistribution vias 113. Additionally, the lower redistribution structure 110 may further include first pads 112P1 and second pads 112P2 disposed on the upper surface (e.g., top surface 110a) thereof. As shown the first pads 112P1 and second pads 112P2 may be electrically connected to the lower redistribution layer 112.

The lower insulating layer 111 may include an insulating resin. The insulating resin may include a thermosetting resin such as epoxy resin, a thermoplastic resin such as polyimide, or a resin in which these resins are impregnated with inorganic fillers, or the like, for example, prepreg, Ajinomoto Build-up Film (ABF), FR-4, or Bismaleimide-Triazine (BT). For example, the lower insulating layer 111 may include a photosensitive resin such as Photo-Imageable Dielectric (PID). The lower insulating layer 111 may include a plurality of insulating layers stacked in the vertical direction D3. Depending on the process, the boundaries between the plurality of insulating layers may be unclear.

The lower redistribution layer 112 is disposed on and within the lower insulating layer 111 and may redistribute the connection terminal 120P of the chip structure 120. The lower redistribution layer 112 may include a metal, for example, copper (Cu), aluminum (Al), silver (Ag), tin (Sn), gold (Au), nickel (Ni), lead (Pb), titanium (Ti), or alloys thereof. The lower redistribution layer 112 may perform various functions depending on the design. For example, the lower redistribution layer 112 may include a ground pattern, a power pattern, and a signal pattern. In some example embodiments, the signal pattern may be defined as a transmission path for various signals, such as data signals, excluding ground patterns, power patterns, or the like. The lower redistribution layer 112 may include more or fewer redistribution layers than illustrative in the drawing.

The lower redistribution layer 112 may be electrically connected to the connection bumps 125 and the plurality of posts 135 through the first pads 112P1 and the second pads 112P2. The first pads 112P1 may have a larger planar area (e.g., larger area in a horizontal plane extending in the horizontal directions D1 and D2) than the second pads 112P2. For example, the first horizontal width d1 of each of the first pads 112P1 may be greater than the second horizontal width d2 of each of the second pads 112P2. The first pads 112P1 may be arranged on at least one side of the chip mounting area 120R, and the second pads 112P2 may be arranged within the chip mounting area 120R. The planar shape (e.g., the shape in the horizontal plane) of the first pads 112P1 and the second pads 112P2 may be circular or polygonal.

The lower redistribution via 113 may extend within the lower insulating layer 111 and be electrically connected to the lower redistribution layer 112. For example, the lower redistribution via 113 may interconnect multiple lower redistribution layers 112 at different levels. The lower redistribution via 113 may electrically connect the first pads 112P1 and the second pads 112P2 to the lower redistribution layer 112. The lower redistribution via 113 may include a signal via, a ground via, and a power via. The lower redistribution via (113) may include, for example, copper (Cu), aluminum (Al), silver (Ag), tin (Sn), gold (Au), nickel (Ni), lead (Pb), titanium (Ti), or a metallic substance including alloys thereof. The lower redistribution via 113 may be a filled via in which the inside of the via-hole is filled with a metal material, or a conformal via in which a metal material extends along the inner wall of the via-hole.

The external connection bumps 160 may be disposed below the lower redistribution structure 110. The external connection bumps 160 may be electrically connected to the lower redistribution layer 112. The semiconductor package 100A may be connected to an external device such as a module substrate or system board through external connection bumps 160. The external connection bumps 160 may include a low melting point metal, for example, tin (Sn) or an alloy containing tin (Sn) (for example, Sn—Ag—Cu). In some example embodiments, the external connection bumps 160 may have a shape that is a combination of a pillar and a ball. In some example embodiments, an Under Bump Metal (UBM) structure may be disposed between the external connection bumps 160 and the lower redistribution layer 112. The UBM structure may include, for example, copper (Cu), aluminum (Al), silver (Ag), tin (Sn), gold (Au), nickel (Ni), lead (Pb), titanium (Ti), or a metallic substance including alloys thereof.

The chip structure 120 is disposed on the second pads 112P2 of the lower redistribution structure 110, and may include connection terminals 120P electrically connected to the second pads 112P2 and the lower redistribution layer 112. The connection terminals 120P may be electrically connected to the lower redistribution layer 112 through connection bumps 125. The connection bumps 125 may include a pillar portion 121 in contact with the connection terminals 120P and a solder portion 123 disposed below the pillar portion 121. The pillar portion 121 may include copper (Cu) or an alloy of copper (Cu), and the solder portion 123 may include a low melting point metal, such as tin (Sn) or an alloy containing tin (Sn). In some example embodiments, the connection bumps 125 may include only one of the pillar portion 121 or the solder portion 123. In some example embodiments, an underfill layer may be disposed between the chip structure 120 and the lower redistribution structure 110. The underfill layer may have a capillary underfill (CUF) structure, but example embodiments are not limited thereto. The underfill layer may have a molded underfill (MUF) structure integrated with the mold layer 130.

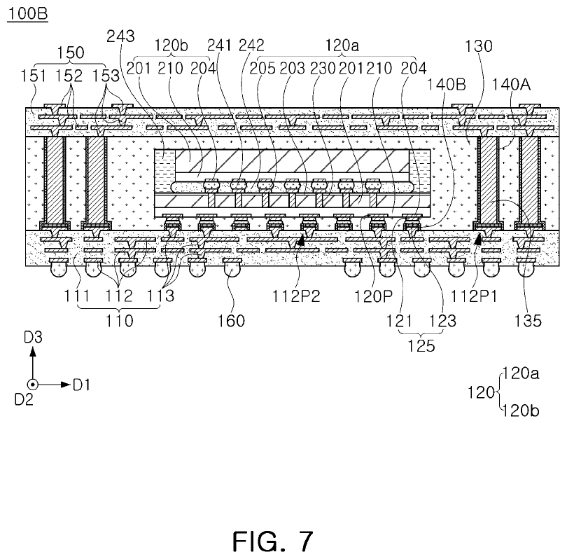

The chip structure 120 may include semiconductor wafers and integrated circuits formed of semiconductor elements such as silicon, germanium, or compound semiconductors such as silicon carbide (SiC), gallium arsenide (GaAs), indium arsenide (InAs), and/or indium phosphide (InP) (Integrated Circuit: IC). The chip structure 120 may be a bare semiconductor chip without separate bumps or interconnection layers, but is not limited thereto, and may be a packaged type semiconductor chip. The chip structure 120 may include a logic circuit (or a ‘logic chip’) such as a Central processor (CPU), a graphics processor (GPU), a field programmable gate array (FPGA), an application processor (AP), a digital signal processor, a cryptographic processor, a microprocessor, a microcontroller, an analog-to-digital converter, an application-specific IC (ASIC), or a memory circuit (or a ‘memory chip’) containing a volatile memory, such as dynamic RAM (DRAM) and static RAM (SRAM), and a non-volatile memory such as phase change RAM (PRAM), magnetic RAM (MRAM), resistive RAM (RRAM), and flash memory. In some example embodiments, the chip structure 120 may be a package structure including a plurality of semiconductor chips, which will be described later with reference to FIG. 7.

The mold layer 130 is disposed on the lower redistribution structure 110 and may cover at least a portion of each of the chip structure 120 and the plurality of posts 135. For example, the mold layer 130 may cover (e.g., overlap in a horizontal direction D1 and/or D2 and/or overlap in a vertical direction D3) at least a portion of the chip structure 120 and at least a portion of each post 135 of the plurality of posts 135. The mold layer 130 may include, for example, a thermosetting resin such as an epoxy resin, a thermoplastic resin such as polyimide, prepreg, ABF, FR-4, BT, or Epoxy Molding Compound (EMC). The mold layer 130 may be spaced apart from the side surfaces of the plurality of posts 135 by the first side barrier layers 140A. Restated, the first side barrier layers 140A may be between the mold layer 130 and respective side surfaces S11 of the first pads 112P1 and between the mold layer 130 and respective side surfaces 135S of the plurality of posts 135. The mold layer 130 may surround the first side barrier layers 140A that cover the outer peripheral surfaces (e.g., side surfaces 135S) of the plurality of posts 135. The mold layer 130 may fill gaps between first side barrier layers 140A adjacent to each other, second side barrier layers 140B adjacent to each other, and first side barrier layers 140A and second side barrier layers 140B adjacent to each other. For example, the mold layer 130 may include a single, unitary piece of material extending continuously between adjacent first side barrier layers 140A, between adjacent second side barrier layers 140B, and between adjacent first and second side barrier layers 140A and 140B.

A plurality of posts 135 may be disposed on the first pads 112P1 of the lower redistribution structure 110. The plurality of posts 135 may electrically connect the lower redistribution layer 112 and the upper redistribution layer 152. The plurality of posts 135 may include copper (Cu), nickel (Ni), titanium (Ti), lead (Pb), aluminum (Al), silver (Ag), gold (Au), platinum (Pt), or alloys thereof. The plurality of posts 135 may include a different metal from the first side barrier layers 140A. For example, the plurality of posts 135 may include copper (Cu) or alloys thereof. The plurality of posts 135 may extend in the vertical direction D3 within the mold layer 130. The plurality of posts 135 may have a cylindrical shape, but are not limited thereto.

According to some example embodiments, by introducing the first side barrier layers 140A between the plurality of posts 135 and the mold layer 130, surface oxidation of the plurality of posts 135 may be reduced, minimized, or prevented, and adhesion between the mold layer 130 and the plurality of posts 135 may be improved, thereby improving the yield and reliability of the semiconductor package 100A as a result. In addition, peeling and cracks between the mold layer 130 and the posts 135 that occur during the upper planarization process of the mold layer 130 may be reduced, minimized, or prevented, and the yield and reliability of the semiconductor package 100A may be improved as a result. The first side barrier layers 140A may be disposed between the mold layer 130 and each side surface of the first pads 112P1 and between the mold layer 130 and each side surface of the plurality of posts 135.

Additionally, according to some example embodiments, second side barrier layers 140B may be disposed between the mold layer 130 and the side surfaces S21 of each of the second pads 112P2. The first side barrier layers 140A and the second side barrier layers 140B may reduce, minimize, or prevent oxidation of the first pads 112P1 and the second pads 112P2, respectively, thereby improving the yield and reliability of the semiconductor package 100A as a result. The first side barrier layers 140A and the second side barrier layers 140B may include a material that is resistant to oxidation, for example, nickel (Ni), gold (Au), silver (Ag), titanium (Ti), or alloys thereof. The first side barrier layers 140A adjacent to each other, the second side barrier layers 140B adjacent to each other, and the first side barrier layers 140A and second side barrier layers 140B adjacent to each other may be spaced apart from each other (e.g., with the mold layer 130 therebetween) and may be electrically isolated from each other.

The upper redistribution structure 150 is disposed on the mold layer 130 and may include an upper insulating layer 151, an upper redistribution layer 152, and an upper redistribution via 153.

The upper insulating layer 151 may include thermosetting resins such as epoxy resins, thermoplastic resins such as polyimide, or resins in which these resins are impregnated with inorganic fillers, for example, prepreg, ABF, FR-4, or BT. For example, the upper insulating layer 151 may include a photosensitive resin such as PID. The upper insulating layer 151 may include a plurality of insulating layers stacked in the vertical direction D3. The upper insulating layer 151 may include more or fewer insulating layers than illustrative in the drawing. Depending on the process, the boundaries between the plurality of insulating layers may be unclear.

The upper redistribution layer 152 may be disposed on and within the upper insulating layer 151. The upper redistribution layer 152 may include, for example, copper (Cu), aluminum (Al), silver (Ag), tin (Sn), gold (Au), nickel (Ni), lead (Pb), titanium (Ti), or metals containing alloys thereof. The upper redistribution layer 152 may include a ground pattern, a power pattern, and a signal pattern depending on the design. The upper redistribution layer 152 may include more or fewer redistribution layers than illustrated in the drawings. In some example embodiments, a barrier film may be formed on the pad portion of the uppermost upper redistribution layer 152. The barrier film may include, for example, nickel (Ni), gold (Au), or alloys thereof.

The upper redistribution via 153 may extend within the upper insulating layer 151 and be electrically connected to the upper redistribution layer 152. The upper redistribution via 153 may interconnect the upper redistribution layers 152 on different levels. The upper redistribution via 153 may include, for example, copper (Cu), aluminum (Al), silver (Ag), tin (Sn), gold (Au), nickel (Ni), lead (Pb), titanium (Ti), or a metallic substance including alloys thereof. The upper redistribution via 153 may be a filled via in which the inside of the via-hole is filled with a metal material, or a conformal via in which a metal material extends along the inner wall of the via-hole. The upper redistribution layer 152 may be electrically connected to the plurality of posts 135 (e.g., via an upper redistribution via 153).

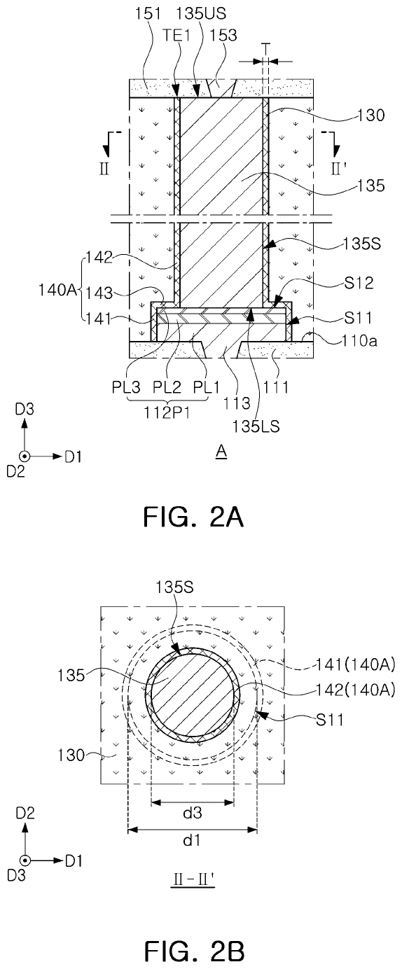

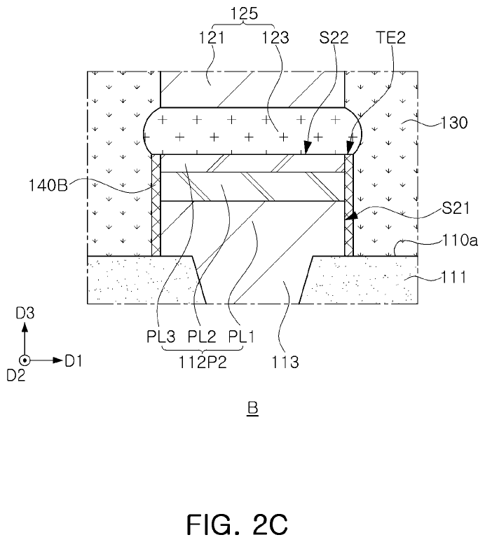

Hereinafter, with reference to FIGS. 2A to 2C, the first side barrier layers 140A and the second side barrier layers 140B will be described in more detail.

FIG. 2A is a partially enlarged view of area ‘A’ in FIG. 1A according to some example embodiments, FIG. 2B is a plan view of line ‘II-II’ in FIG. 2A according to some example embodiments, and FIG. 2C is a partially enlarged view of area ‘B’ in FIG. 1A according to some example embodiments.

Referring to FIGS. 2A to 2C, the first side barrier layers 140A may cover (and may contact) at least a portion of each first pad of the first pads 112P1 and at least a portion of each post of the plurality of posts 135. Each of the first side barrier layers 140A may include a lower barrier layer 141 surrounding one or more side surfaces S11 of one or more first pads 112P1 of the first pads 112P1, and an upper barrier layer 142 surrounding one or more side surfaces 135S of one or more posts 135 of the plurality of posts 135. Each first side barrier layer 140A may include a lower barrier layer 141 on a respective one or more side surfaces S11 of a respective one or more first pads 112P1 of the first pads 112P1, and an upper barrier layer 142 surrounding a respective side surface 135S of a respective one or more posts 135 of the plurality of posts 135. In some example embodiments, at least some of the first side barrier layers 140A may further include a middle barrier layer 143 connecting the lower barrier layer 141 and the upper barrier layer 142. The middle barrier layer 143 may extend in the horizontal direction D1 and D2 along the outer portion of one or more upper surfaces S12 of one or more first pads 112P1 exposed from one or more posts 135. For example, each first side barrier layer 140A may include a lower barrier layer 141 on a respective one or more side surfaces S11 of a respective one or more first pads 112P1 of the first pads 112P1, an upper barrier layer 142 on one or more side surfaces 135S of a respective one or more posts 135 of the plurality of posts 135, and a middle barrier layer 143 connecting the lower barrier layer 141 to the upper barrier layer 142 and extending along a respective one or more upper surfaces S12 of the respective one or more first pads 112P1 of the first pads 112P1.

As shown, the horizontal directions D1 and D2 may each extend in parallel with the lower redistribution structure 110, a top surface 110a of the lower redistribution structure 110, a bottom surface 110b of the lower redistribution structure 110, or the like. The horizontal directions D1 and D2 may be different (e.g., perpendicular) from each other. The vertical direction D3 may extend perpendicular to the lower redistribution structure 110, the top surface 110a of the lower redistribution structure 110, the bottom surface 110b of the lower redistribution structure 110, or the like and thus may be perpendicular to both of the horizontal directions D1 and D2. As shown, the top surface 110a of the lower redistribution structure 110 may be entirely or partially defined by an upper surface of the insulation layer 111. As shown, the bottom surface 110b of the lower redistribution structure 110 may be entirely or partially defined by a lower surface of the insulation layer 111.

The first side barrier layers 140A may extend conformally along and may contact one or more surfaces of the first pads 112P1 and the plurality of posts 135 (e.g., surfaces S11, S12, S135). The thickness T of each of the first side barrier layers 140A may be 100 nm or less (e.g., greater than 0 nm and equal to or smaller than 100 nm, between about 0.01 nm and about 100 nm, between about 0.1 nm and about 100 nm, between about 1 nm and about 100 nm, etc.). For example, the thickness T of each of the first side barrier layers 140A may range from several nm to several tens of nm, but is not limited thereto. In some example embodiments, the lower barrier layer 141, the upper barrier layer 142, and the middle barrier layer 143 may have the same or substantially the same thickness T.

Each of the plurality of posts 135 may have a side surface 135S in contact with at least one of the first side barrier layers 140A, a lower surface 135LS exposed from the first side barrier layers 140A and in contact with at least one of the first pads 112P1, and an upper surface 135US exposed from the first side barrier layers 140A and in contact with the upper redistribution via 153. The upper surface 135US of the plurality of posts 135 may be coplanar with the upper end TE1 of the first side barrier layers 140A. The first horizontal width (e.g., diameter) d1 of each of the first pads 112P1 may be greater than the third horizontal width (e.g., diameter) d3 of each of the plurality of posts 135. For example, in a plan view (e.g., in the horizontal directions D1 and/or D2), the diameter d1 of the inner peripheral surface of the lower barrier layer 141 may be larger (e.g., greater) than the diameter d3 of the inner peripheral surface of the upper barrier layer 142.

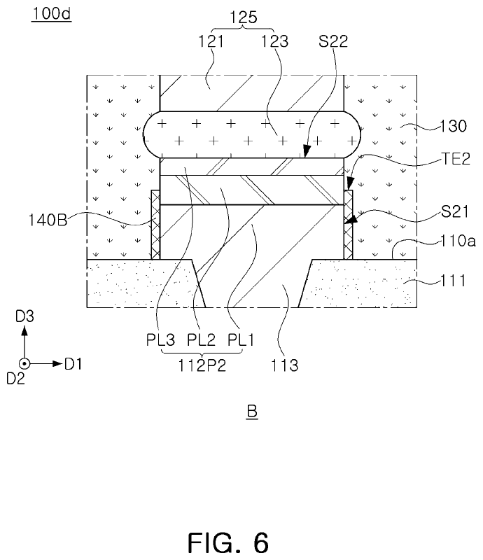

The second side barrier layers 140B may cover (and may contact) at least a portion of each second pad of the second pads 112P2. The second side barrier layers 140B may surround the side surfaces S21 of each of the second pads 112P2. The second side barrier layers 140B may be between the mold layer 130 and respective side surfaces S21 of the second pads 112P2. One or more upper surfaces S22 of the second pads 112P2 may be exposed from the second side barrier layers 140B. The upper surfaces S22 of the second pads 112P2 may be in contact with the solder portions 123 of the connection bumps 125. One or more upper ends TE2 of the second side barrier layers 140B may be in contact with one or more solder portions 123, but example embodiments are not limited thereto. In some example embodiments, one or more upper ends TE2 of the second side barrier layers 140B may be spaced apart from one or more respective solder portions 123 (see FIG. 6). The second side barrier layers 140B may include the same material as the first side barrier layers 140A. In some example embodiments, the second side barrier layers 140B may include at least one different material than that of the first side barrier layers 140A. Additionally, the second side barrier layers 140B may have the same or substantially the same thickness as the first side barrier layers 140A. The thickness of each of the second side barrier layers 140B may be 100 nm or less (e.g., greater than 0 nm and equal to or smaller than 100 nm, between about 0.01 nm and about 100 nm, between about 0.1 nm and about 100 nm, between about 1 nm and about 100 nm, etc.). The first side barrier layers 140A and the second side barrier layers 140B may each independently have a thickness greater than 0 nm and equal to or smaller than 100 nm.

The first pads 112P1 and the second pads 112P2 may each be composed of a single metal layer or a multi-layer metal layer. In some example embodiments, each of the first pads 112P1 and the second pads 112P2 may include a first metal layer PL1 connected to the lower redistribution via 113, a second metal layer PL2 on the first metal layer PL1, and a third metal layer PL3 on the second metal layer PL2 such that the second metal layer PL2 is between the first and third metal layers PL1 and PL3 in the vertical direction D3. For example, the first metal layer may include copper (Cu), the second metal layer PL2 may include nickel (Ni), and the third metal layer PL3 may include gold (Au). In some example embodiments, the second metal layer PL2 and the third metal layer PL3 may be omitted or may be formed of a metal other than those described above.

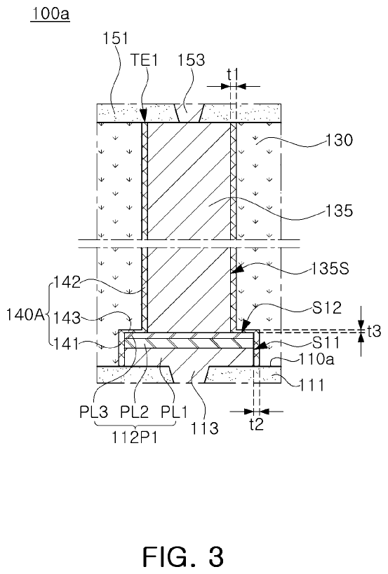

FIG. 3 is a partially enlarged view of area ‘A’ of FIG. 1A illustrating the semiconductor package 100a of an illustrative modification according to some example embodiments.

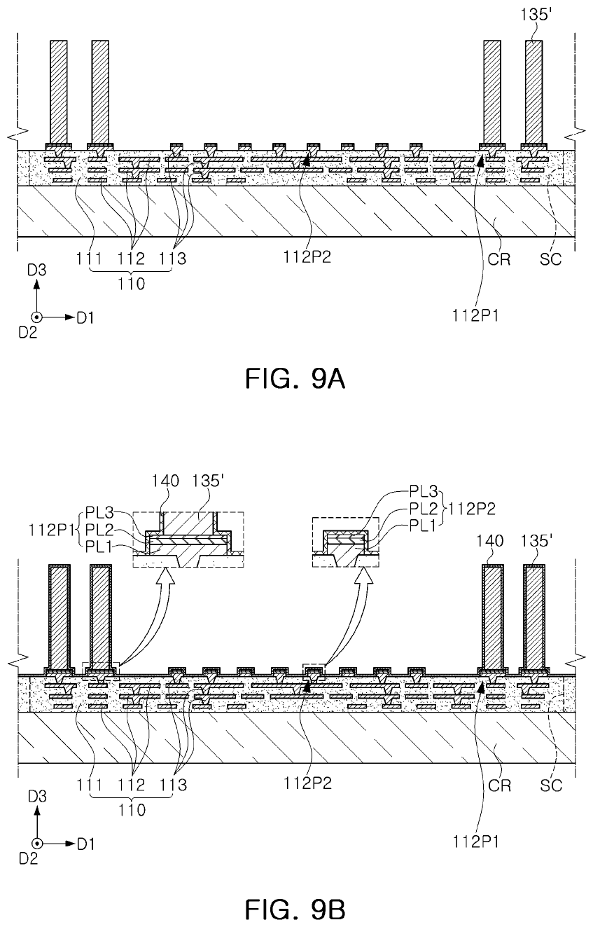

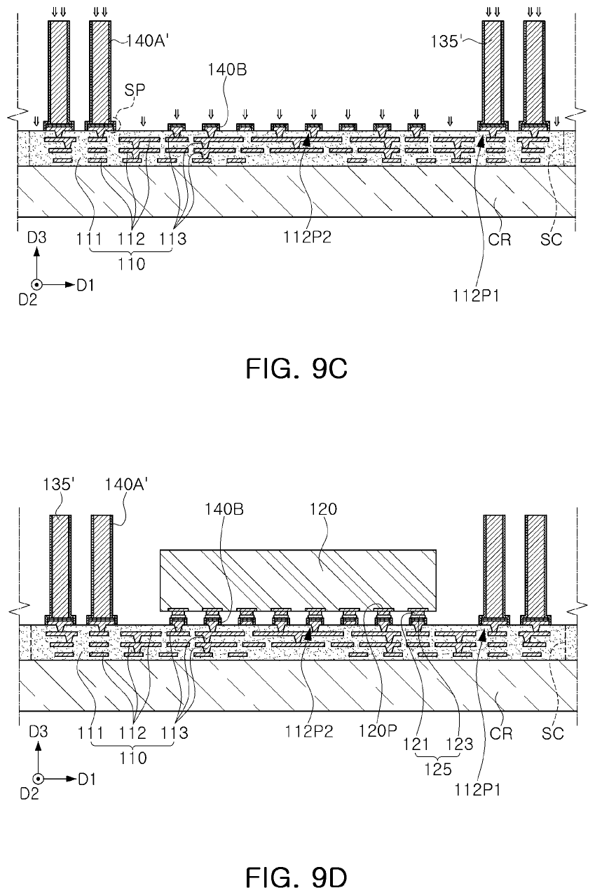

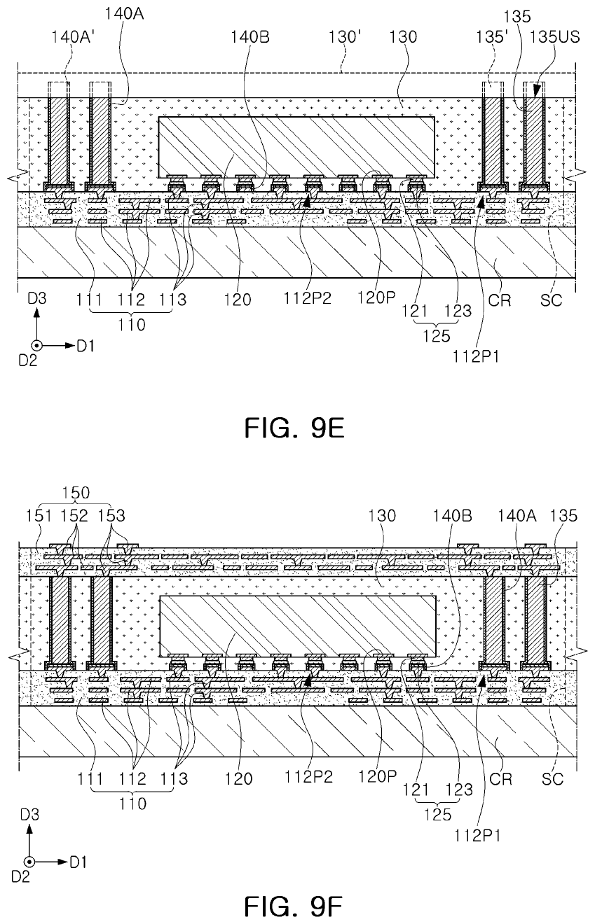

Referring to FIG. 3, the semiconductor package 100a of the modified example may have the same or similar features as those described with reference to FIGS. 1A to 2C, except that at least some of one or more of the first side barrier layers 140A have different thicknesses in some areas. In a variation, each of the first side barrier layers 140A may include a lower barrier layer 141 on one or more (e.g., each) side surfaces S11 of one or more of the first pads 112P1, an upper barrier layer 142 on one or more (e.g., each) side surfaces 135S of one or more posts 135 of the plurality of posts 135, and a middle barrier layer 143 connecting the lower barrier layer 141 and the upper barrier layer 142 (e.g., on an upper surface S12 of one or more of the first pads 112P1). The middle barrier layer 143 may have a relatively small thickness by an anisotropic etching process (see FIG. 9C), which will be described later. The thickness t3 of the middle barrier layer 143 may be smaller than the thickness t1 of the lower barrier layer 141 and the thickness of the upper barrier layer t2.

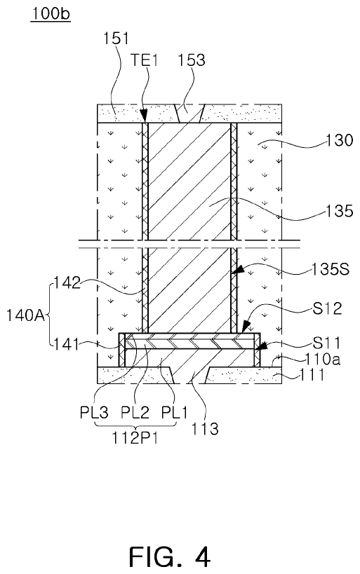

FIG. 4 is a partially enlarged view of area ‘A’ of FIG. 1A illustrating a semiconductor package 100b of an illustrative modification according to some example embodiments.

Referring to FIG. 4, the semiconductor package 100b of the modified example may have the same or similar features as those described with reference to FIGS. 1A to 3, except that at least some of the first side barrier layers 140A do not include a middle barrier layer. In a variation, each of the first side barrier layers 140A may include a lower barrier layer 141 on one or more side surfaces S11 of one or more of the first pads 112P1, and an upper barrier layer 142 on one or more side surface 135S of one or more of the posts 135. The lower barrier layer 141 and the upper barrier layer 142 may be spaced apart from each other. At least a portion of one or more upper surfaces S12 of one or more of the first pads 112P1 may be in contact with the mold layer 130 (e.g., may be exposed to the mold layer 130 from the first side barrier layers 140A). For example, an upper surface S12 of one or more of the first pads 112P1 may include a central portion where the plurality of posts 135 are disposed and an outer portion exposed from the plurality of posts 135 and the upper barrier layer 142.

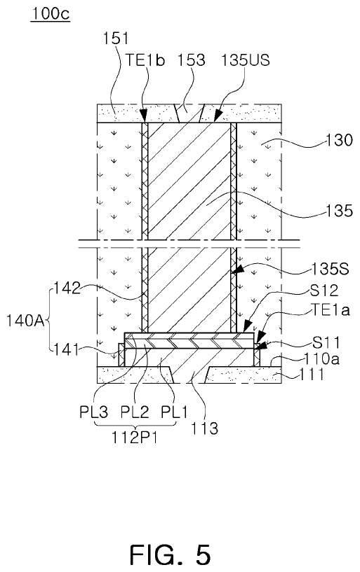

FIG. 5 is a partially enlarged view of area ‘A’ of FIG. 1A illustrating a semiconductor package 100c of an illustrative modification according to some example embodiments.

Referring to FIG. 5, the semiconductor package 100c of the modified example may have the same or similar features as those described with reference to FIGS. 1A to 4, except that at least some of the first side barrier layers 140A do not include a middle barrier layer and the lower barrier layer 141 does not cover at least a portion of the side surface S11 of the first pads 112P1. In a variation, each of the first side barrier layers 140A may include a lower barrier layer 141 on one or more side surfaces S11 of one or more first pads 112P1, and an upper barrier layer 142 on one or more side surfaces 135S of one or more posts 135 of the plurality of posts 135. The lower barrier layer 141 and the upper barrier layer 142 may be spaced apart from each other. At least a portion of one or more upper surfaces S12 of the one or more first pads 112P1 may be in contact with the mold layer 130. For example, an upper surface S12 of one or more of the first pads 112P1 may include a central portion where one or more posts 135 of the plurality of posts 135 are disposed and an outer portion exposed from the plurality of posts 135 and the upper barrier layer 142.

The upper end TE1a of the lower barrier layer 141 may be located at the same level as or a lower level than (e.g., at a same level or a lower level in relation to) one or more upper surfaces S12 of a respective one or more first pads 112P1. The upper end TE1b of the upper barrier layer 142 is in contact with the upper insulating layer 151 and may be coplanar with one or more upper surfaces 135US of a respective one or more posts 135 of the plurality of posts 135. A portion of one or more side surfaces S11 of one or more first pads 112P1 may be exposed from the lower barrier layer 141 and may be in contact with the mold layer 130.

As described herein, a “height,” “level,” “vertical level,” or the like of an element, structure, surface, or the like may refer to a distance of the element, structure, surface, or the like from a reference location (e.g., the lower redistribution structure 110, the top surface 110a of the lower redistribution structure 110, the bottom surface 110b of the lower redistribution structure 110, or the like) in the vertical direction D3. Accordingly, where an element is described to have a same, higher, or lower level than another element, it will be understood that the element is at a same, greater, or smaller distance in the vertical direction D3, respectively, from a reference location (e.g., the lower redistribution structure 110, the top surface 110a of the lower redistribution structure 110, the bottom surface 110b of the lower redistribution structure 110, or the like) than the other element. The top surface 110a of the lower redistribution structure 110 may be an upper surface of the lower insulating layer 111. The bottom surface 110b of the lower redistribution structure 110 may be a lower surface of the lower insulating layer 111.

FIG. 6 is a partially enlarged view of area ‘B’ of FIG. 1A illustrating a semiconductor package 100d of an illustrative modification according to some example embodiments.

Referring to FIG. 6, the semiconductor package 100d of the modified example may have the same or similar features as those described with reference to FIGS. 1A to 5, except that the second side barrier layers 140B do not cover (e.g., expose) at least a portion of one or more side surfaces S21 of one or more of the second pads 112P2. In a modified example, the upper end TE2 of the second side barrier layers 140B may be located at the same level as or a lower level than (e.g., at a same level or a lower level in relation to) one or more upper surfaces S22 of one or more of the second pads 112P2. The upper end TE2 of one or more of the second side barrier layers 140B may be spaced apart from one or more solder portions 123. A portion of one or more side surfaces S21 of one or more second pads 112P2 of the second pads 112P2 is exposed from the second side barrier layers 140B and may be in contact with the mold layer 130.

FIG. 7 is a cross-sectional view of a semiconductor package 100B according to some example embodiments.

Referring to FIG. 7, the semiconductor package 100B according to some example embodiments may have the same or similar features as those described with reference to FIGS. 1A to 6, except that it includes a chip structure 120 in which a plurality of semiconductor chips 120a and 120b are embedded.

At least some of the plurality of semiconductor chips 120a and 120b (for example, ‘120a’) may include through-vias 230 that electrically connect the plurality of semiconductor chips 120a and 120b to each other. The plurality of semiconductor chips 120a and 120b may be chiplets constituting a multi-chip module (MCM). The plurality of semiconductor chips 120a and 120b may include a central processor (CPU), a graphics processor (GPU), a field programmable gate array (FPGA), a digital signal processor (DSP), a cryptographic processor, a microprocessor, a microcontroller, an analog-to-digital converter, an application-specific integrated circuit (ASIC), a volatile memory, a non-volatile memory, an input/output (I/O) circuit, an analog circuit, a serial-parallel conversion circuit, and the like.

In some example embodiments, the chip structure 120 may include a base chip 120a and at least one stack chip 120b. For example, the base chip 120a includes a processor circuit, and at least one stack chip 120b may include at least one of an input/output circuit for a processor circuit, an analog circuit, a memory circuit, and a serial-parallel conversion circuit. The base chip 120a and at least one stack chip 120b may be provided in larger numbers than illustrative in the drawing. For example, at least one stack chip 120b may include two or more semiconductor chips arranged horizontally and/or vertically on the base chip 120a.

The base chip 120a and at least one stack chip 120b may include a substrate 201, an upper protective layer 203, an upper pad 205, a circuit layer 210, a lower pad 204, and/or a through-via 230. The substrate 201 may include, for example, a semiconductor element such as silicon or germanium (Ge), or may include a compound semiconductor such as silicon carbide (SiC), gallium arsenide (GaAs), indium arsenide (InAs), or indium phosphide (InP). The substrate 201 may have a silicon on insulator (SOI) structure. The substrate 201 may have a conductive region, for example, a well doped with an impurity, or an active side doped with an impurity and an inactive side vice versa. The substrate 201 may include various device isolation structures, such as a shallow trench isolation (STI) structure.

The upper protective layer 203 is formed on the inactive side of the substrate 201 and may protect the substrate 201. The upper protective layer 203 may be formed of an insulating layer such as a silicon oxide film, a silicon nitride film, or a silicon oxynitride film, but the material of the upper protective layer 203 is not limited to the above materials. Although not illustrative in the drawing, a lower protective layer may be further formed on the lower surface of the circuit layer 210.

The upper pad 205 may be disposed on the upper protective layer 203. The upper pad 205 may include, for example, at least one of aluminum (Al), copper (Cu), nickel (Ni), tungsten (W), platinum (Pt), and gold (Au). The lower pad 204 may be disposed below the circuit layer 210 and may include a material similar to the upper pad 205. However, the materials of the upper pad 205 and lower pad 204 are not limited to the above materials. The lower pad 204 of the base chip 120a may be understood as corresponding to the connection terminals 120P described above.

The circuit layer 210 is disposed on the active surface of the substrate 201 and may include various types of devices. For example, the circuit layer 210 may include FETs such as planar Field Effect Transistor (FET) or FinFET, memory elements such as a flash memory, a Dynamic Random Access Memory (DRAM), a Static Random Access Memory (SRAM), an Electrically Erasable Programmable Read-Only Memory (EEPROM), a Phase-change Random Access Memory (PRAM).), a Magnetoresistive Random Access Memory (MRAM), a Ferroelectric Random Access Memory (FeRAM), a Resistive Random Access Memory (RRAM), and the like, logic elements such as AND, OR, NOT, and the like, and various active and/or passive elements such as System Large Scale Integration (LSI), CMOS Imaging Sensor (CIS), and Micro-Electro-Mechanical System (MEMS). The circuit layer 210 may include an interconnection structure electrically connected to the above-described elements and an interlayer insulating layer surrounding the interconnection structure. The interlayer insulating layer may include silicon oxide or silicon nitride. The interconnect structure may include multilayer interconnects and/or vertical contacts. The interconnection structure may connect elements of the circuit layer 210 to each other, connect elements to conductive regions of the substrate 201, or connect elements to the through-via 230.

The base chip 120a is disposed below the at least one stack chip 120b and may include through-vias 230 electrically connected to the at least one stack chip 120b. The through-via 230 penetrates the substrate 201 in the vertical direction D3 and may provide an electrical path connecting the upper pad 205 and the lower pads 204. The through-via 230 may include a conductive plug and a barrier film surrounding it. The conductive plug may include a metal, such as tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may be formed of an oxide film, a nitride film, a carbonization film, a polymer, or a combination thereof. The conductive barrier film may be disposed between the insulating barrier film and the conductive plug. The conductive barrier film may include a metal compound such as tungsten nitride (WN), titanium nitride (TiN), or tantalum nitride (TaN), for example. The barrier film may be formed by a PVD process or a CVD process.

The base chip 120a and at least one stack chip 120b may be electrically connected through bumps 241. The bumps 241 may be disposed in the adhesive layer 242 between the base chip 120a and at least one stack chip 120b. The bumps 241 may include tin (Sn), indium (In), bismuth (Bi), antimony (Sb), copper (Cu), silver (Ag), zinc (Zn), lead (Pb) and/or alloys thereof, and in some example embodiments, may have a combination of metal pillars and solder balls. The adhesive layer 242 surrounds each of the bumps 241 and may bond the base chip 120a and at least one stack chip 120b. The adhesive layer 242 may be formed using NCF (Non Conductive Film), but is not limited thereto, and may be formed, for example, using any type of insulating film capable of a heat compression process. In some example embodiments, the base chip 120a and the at least one stack chip 120b may be connected by directly bonding and combining the corresponding upper pad 205 and lower pad 204 without bumps 241.

At least one stack chip 120b may be sealed by a mold 243. The mold 243 may surround the outer surface of at least one stack chip 120b and the adhesive layer 242 on the base chip 120a. The mold 243 may include an insulating material, such as EMC, for example.

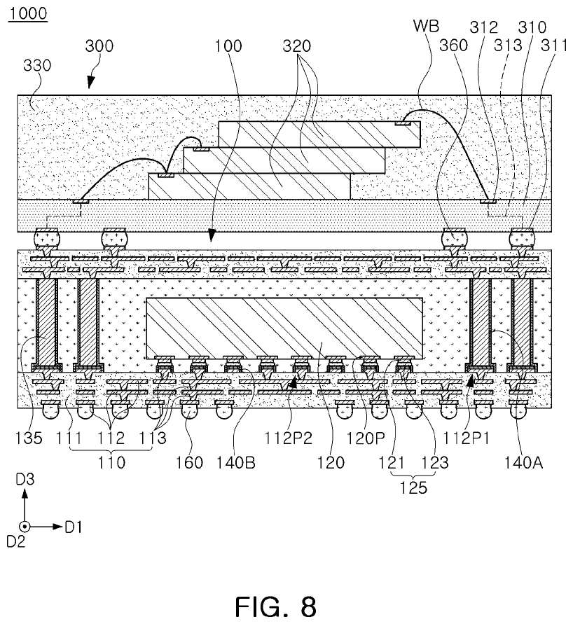

FIG. 8 is a cross-sectional view of a semiconductor package 1000 according to some example embodiments.

Referring to FIG. 8, the semiconductor package 1000 according to some example embodiments may include a lower package 100 and an upper package 300. The lower package 100 is illustrative identically to the semiconductor package 100A illustrative in FIG. 1A, but may be replaced with the semiconductor packages 100a, 100b, 100c, 100d, and 100B described with reference to FIGS. 1A to 7 or semiconductor packages having characteristics similar thereto. The semiconductor package 1000 of some example embodiments includes a lower package 100 into which first and/or second side barrier layers 140A and 140B are introduced, and may be implemented as a package-on-package structure having improved reliability and yield.

The upper package 300 may include an interconnection board 310, a semiconductor chip 320, and an encapsulant 330. The interconnection board 310 may include a lower pad 311 and an upper pad 312. Additionally, the interconnection board 310 may include an interconnection circuit 313 that electrically connects the lower pad 311 and the upper pad 312. The interconnection board 310 may be a semiconductor package board including a printed circuit board (PCB), a ceramic board, a glass board, a tape interconnection board, and the like. For example, the interconnection board 310 may be a double-sided PCB or a multi-layer PCB.

The semiconductor chip 320 may be mounted on the interconnection board 310 using a wire bonding or flip chip bonding method. For example, the plurality of semiconductor chips 320 may be stacked in a vertical direction on the interconnection board 310 and electrically connected to the upper pad 312 of the interconnection board 310 through a bonding wire WB. In an example, the semiconductor chip 320 of the upper package 300 may include a memory chip, and the chip structure 120 of the lower package 100 may include an AP chip.

The encapsulant 330 may include the same or similar material as the mold layer 130 of the lower package 100. The upper package 300 may be physically and electrically connected to the lower package 100 by a conductive bump 360. The conductive bump 360 may include a low melting point metal, for example, tin (Sn) or an alloy containing tin (Sn).

FIGS. 9A, 9B, 9C, 9D, 9E, and 9F are diagrams illustrating a manufacturing process of a semiconductor package according to some example embodiments.

Referring to FIG. 9A, a lower redistribution structure 110 and preliminary posts 135′ may be formed on the carrier substrate CR. The carrier substrate (CR) may be a temporary support including a glass wafer, a curable resin layer, and the like. The lower redistribution structure 110 may be formed at a wafer level. A plurality of lower redistribution structures 110 divided by scribe lanes (SC) may be formed on the carrier substrate (CR).

The lower redistribution structure 110 may include a lower insulating layer 111, a lower redistribution layer 112, and a lower redistribution via 113. The lower insulating layer 111 may be formed by sequentially applying and curing a photosensitive material, for example, PID. The lower redistribution layer 112 and the lower redistribution via 113 may be formed by performing an exposure process and a development process to form a via-hole penetrating the lower insulating layer 111, and by patterning a metal material on the lower insulating layer 111 using a plating process. The first pads 112P1 and the second pads 112P2 may be formed on the upper surface of the lower redistribution structure 110.

The preliminary posts 135′ may be formed on the first pads 112P1 by performing a plating process. The preliminary posts 135′ may include a metal material such as copper (Cu). In some example embodiments, a metal seed layer (not illustrative) containing titanium (Ti), copper (Cu), or the like may be formed on the lower surfaces of the preliminary posts 135′.

Referring to FIG. 9B, a barrier material layer 140 may be formed covering the surfaces of the lower redistribution structure 110 and the preliminary posts 135′. The barrier material layer 140 may be formed through a plating process or a deposition process. For example, the barrier material layer 140 may be formed through an electroless plating process, but is not limited thereto. The barrier material layer 140 may extend conformally along the surfaces of the preliminary posts 135′ and the first and second pads 112P1 and 112P2. The barrier material layer 140 may be formed as a single-layer or multi-layer thin film. The barrier material layer 140 may include, for example, nickel (Ni), gold (Au), silver (Ag), titanium (Ti), or the like. In some example embodiments, the barrier material layer 140 may be selectively formed only on the side surfaces of the preliminary posts 135′ and the side surfaces of the first and second pads 112P1 and 112P2. The barrier material layer 140 may reduce, minimize, or prevent surface oxidation of the side surfaces of the preliminary posts 135′ and the first and second pads 112P1 and 112P2, and improve the adhesion of the mold layer (or preliminary mold layer) in a subsequent process, thereby improving the yield and reliability of a semiconductor package manufactured according to the manufacturing process shown in at least FIGS. 9A to 9B.

Referring to FIG. 9C, a first preliminary barrier layer 140A′ and a second side barrier layer 140B may be formed. The first preliminary barrier layer 140A′ and the second side barrier layer 140B may be formed by partially removing the barrier material layer 140. Horizontal portions of the barrier material layer 140, for example, a horizontal portion on the upper surface of the preliminary posts 135′, a horizontal portion on the first and second pads 112P1 and 112P2, and a horizontal portion between preliminary posts 135′ and first and second pads 112P1 and 112P2 may be removed. Horizontal portions of the barrier material layer 140 may be removed by an anisotropic etching process, for example, a dry etching process. In some example embodiments, the horizontal portion of the barrier material layer 140 is removed from the outer portion SP of the first pads 112P1, and the thickness of the first preliminary barrier layer 140A′ is partially reduced (FIG. 3), or the upper surfaces of the first pads 112P1 may be partially exposed from the first preliminary barrier layer 140A′ (see FIGS. 4 and 5).

Referring to FIG. 9D, a semiconductor chip 120 may be mounted on the lower redistribution structure 110. The semiconductor chip 120 may be mounted using a flip-chip method. For example, the semiconductor chip 120 may connect a connection bump 125 formed on a connection terminal 120P to the second pads 112P2. In some example embodiments, an underfill may be formed between the semiconductor chip 120 and the lower redistribution structure 110.

Referring to FIG. 9E, a mold layer 130 may be formed covering the semiconductor chip 120 and the plurality of posts 135. The mold layer 130 may be formed by applying a planarization process, such as a grinding process or a Chemical Mechanical Polishing (CMP) process, to the preliminary mold layer 130′. The preliminary mold layer 130′ may be formed by applying and curing a molding material, for example, EMC. Through the planarization process, the first side barrier layer 140A and a plurality of posts 135 may be formed by partially removing the first preliminary barrier layer 140A′ and the preliminary posts 135′, respectively. The first preliminary barrier layer 140A′ or the first side barrier layer 140A may reduce, minimize, or prevent peeling and cracking of the preliminary mold layer 130′ during the planarization process, thereby improving the yield and reliability of a semiconductor package manufactured according to the manufacturing process shown in at least FIGS. 9A to 9E. Through the planarization process, a flat surface comprised of the upper surface 135US of the plurality of posts 135, the upper surface of the mold layer 130, and the upper end of the first side barrier layer 140A may be formed.

Referring to FIG. 9F, an upper redistribution structure 150 may be formed. The upper redistribution structure 150 may include upper insulating layers 151, an upper redistribution layer 152, and an upper redistribution via 153. The upper redistribution structure 150 may be formed by repeating a process similar to that of the lower redistribution structure 110 described above. Thereafter, a cutting process is performed along the scribe lane (SC) to separate the unit packages, open the lower insulating layer 111, and then form external connection bumps 160 (see FIG. 1A).

As set forth above, according to some example embodiments, a semiconductor package having improved reliability and yield may be provided by introducing a side barrier layer between a mold layer and posts.

While some example embodiments have been illustrated and described above, it will be apparent to those skilled in the art that modifications and variations could be made without departing from the scope of the present inventive concepts as defined by the appended claims.

What is claimed is:

1. A semiconductor package, comprising:
a lower redistribution structure, the lower redistribution structure including
a lower redistribution layer, and
first pads and second pads electrically connected to the lower redistribution layer;
a plurality of posts on the first pads of the lower redistribution structure;
a semiconductor chip on the second pads of the lower redistribution structure, the semiconductor chip including connection pads electrically connected to the second pads;
a mold layer covering at least a portion of each post of the plurality of posts and at least a portion of the semiconductor chip;
first side barrier layers between the mold layer and respective side surfaces of the first pads and between the mold layer and respective side surfaces of the plurality of posts;
second side barrier layers between the mold layer and respective side surfaces of the second pads;
an upper redistribution structure on the mold layer, the upper redistribution structure including an upper redistribution layer electrically connected to the plurality of posts; and
external connection bumps below the lower redistribution structure, the external connection bumps electrically connected to the lower redistribution layer.

2. The semiconductor package of claim 1, wherein a first horizontal width of each first pad of the first pads is greater than a second horizontal width of each second pad of the second pads.

3. The semiconductor package of claim 1, wherein a first horizontal width of each first pad of the first pads is greater than a third horizontal width of each post of the plurality of posts.

4. The semiconductor package of claim 1, wherein,
the lower redistribution structure further includes a lower redistribution via connecting the first pads and the second pads to the lower redistribution layer, and
each pad of the first pads and the second pads includes
a first metal layer connected to the lower redistribution via,
a second metal layer on the first metal layer, and
a third metal layer on the second metal layer.

5. The semiconductor package of claim 4, wherein,
the first metal layer includes copper (Cu),
the second metal layer includes nickel (Ni), and
the third metal layer includes gold (Au).

6. The semiconductor package of claim 1, wherein,
the first side barrier layers are adjacent to each other,
the second side barrier layers are adjacent to each other, and
the first side barrier layers and the second side barrier layers are electrically insulated.

7. The semiconductor package of claim 6, wherein the mold layer extends between the first side barrier layers, between the second side barrier layers, and between the first side barrier layers and the second side barrier layers.

8. The semiconductor package of claim 1, wherein each first side barrier layer of the first side barrier layers includes
a lower barrier layer on a side surfaces of a respective first pad of the first pads,
an upper barrier layer on a side surface of a respective post of the plurality of posts, and
a middle barrier layer connecting the lower barrier layer to the upper barrier layer and extending along an upper surface of the respective first pad.

9. The semiconductor package of claim 8, wherein a thickness of the middle barrier layer is smaller than each of a thickness of the lower barrier layer and a thickness of the upper barrier layer.

10. The semiconductor package of claim 1, wherein
each first side barrier layer of the first side barrier layers includes
a lower barrier layer on a side surface of a respective first pad of the first pads, and
an upper barrier layer on a side surface of a respective post of the plurality of posts, and
the lower barrier layer and the upper barrier layer are spaced apart from each other.

11. The semiconductor package of claim 10, wherein at least a portion of an upper surface of each first pad of the first pads is in contact with the mold layer.

12. The semiconductor package of claim 10, wherein an upper end of the lower barrier layer is at a same level or a lower level in relation to an upper surface of each of the first pads.

13. The semiconductor package of claim 1, wherein an upper end of each second side barrier layer of the second side barrier layers is at a same level or a lower level in relation to an upper surface of each of the second pads.

14. The semiconductor package of claim 1, wherein the first side barrier layers and the second side barrier layers each independently have a thickness greater than 0 nm and equal to or smaller than 100 nm.

15. The semiconductor package of claim 1, wherein the first side barrier layers and the second side barrier layers each independently include at least one of nickel (Ni), gold (Au), silver (Ag), or titanium (Ti).

16. The semiconductor package of claim 1, wherein the mold layer includes an Epoxy Molding Compound (EMC).

17. A semiconductor package, comprising:
a lower redistribution structure, the lower redistribution structure including
a lower redistribution layer, and
first pads and second pads electrically connected to the lower redistribution layer;
a plurality of posts on the first pads of the lower redistribution structure;
a semiconductor chip on the second pads of the lower redistribution structure;
a mold layer covering at least a portion of each post of the plurality of posts and at least a portion of the semiconductor chip;
side barrier layers between the mold layer and respective side surfaces of the first pads and between the mold layer and respective side surfaces of the plurality of posts;
an upper redistribution structure on the mold layer, the upper redistribution structure including an upper redistribution layer electrically connected to the plurality of posts; and
external connection bumps below the lower redistribution structure, the external connection bumps electrically connected to the lower redistribution layer,
wherein the side barrier layers and the plurality of posts include different metals.

18. The semiconductor package of claim 17, wherein
the side barrier layers each include at least one of nickel (Ni), gold (Au), silver (Ag), or titanium (Ti), and
the plurality of posts each contain copper (Cu).

19. The semiconductor package of claim 17, wherein
each side barrier layer of the side barrier layers includes
a lower barrier layer surrounding a side surface of a respective first pad of the first pads, and
an upper barrier layer surrounding a side surface of a respective post of the plurality of posts, and
in plan view, a diameter of an inner peripheral surface of the lower barrier layer is greater than a diameter of an inner peripheral surface of the upper barrier layer.

20. A semiconductor package, comprising:
a lower redistribution structure, the lower redistribution structure including
a lower redistribution layer, and
first pads and second pads electrically connected to the lower redistribution layer;
a plurality of posts on the first pads of the lower redistribution structure;
a semiconductor chip on the second pads of the lower redistribution structure;
a mold layer covering at least a portion of each post of the plurality of posts and at least a portion of the semiconductor chip;
side barrier layers between the mold layer and respective first pads of the first pads and between the mold layer and respective posts of the plurality of posts; and
an upper redistribution structure on the mold layer, the upper redistribution structure including
an upper redistribution layer, and
an upper redistribution via electrically connecting the upper redistribution layer and the plurality of posts,
wherein each post of the plurality of posts has
a side surface in contact with at least one of the side barrier layers,
a lower surface exposed from the side barrier layers and in contact with at least one of the first pads, and
an upper surface exposed from the side barrier layers and in contact with the upper redistribution via.
